(19) United States
(12) Patent Application Publication
(10) Pub. No.: US 2007/0153890 A1
(43) Pub. Date: Jul. 5, 2007

(54) Pulse width modulation method

(76) Inventors: Norbert Huber, Teisendorf (DE); Franz Ritz, Uebersee (DE); Hans Lengenfelder, Muehldorf (DE)

Correspondence Address: KENYON & KENYON LLP, ONE BROADWAY, NEW YORK, NY, 10004, US

(21) Appl. No.: 11/634,131

(22) Filed: Dec. 4, 2006

(30) Foreign Application Priority Data
Dec. 2, 2005 (DE) 10 2005 057 719.9
Dec. 22, 2005 (DE) 10 2005 061 388.8

(51) Int. Cl. H03K 7/08

(52) U.S. Cl. 375/238

(57) ABSTRACT

A method is for the pulse width modified control of switching elements in a frequency converter having N phases, in which for each phase the control pulses of the switching elements are derived from, in each case, one P-periodic control voltage. The P-periodic control voltages correspond to a superposition of sinusoidal control voltages of period P, that are shifted by 360/N degrees with respect to one another, by an N*P-periodic offset voltage that applies to all phases. The offset voltage is selected such that, at any time, exactly one of the P-periodic control voltages lies effectively on a modulating limit for the derivation of the switching pulses. Using this method, the excitation of resonances at the star point of a connected load may be clearly reduced.

### CROSS-REFERENCE TO RELATED APPLICATIONS

The present application claims priority to Application No. 10 2005 057 719.9, filed in the Federal Republic of Germany on Dec. 2, 2005, and Application No. 10 2005 061 388.8, filed in the Federal Republic of Germany on Dec. 22, 2005, each of which is expressly incorporated herein in its entirety by reference thereto.

### FIELD OF THE INVENTION

The present invention relates to a pulse width modulation method, which may provide for reducing the excitation of resonances in a multiphase system that includes a network, a frequency converter and a motor.

### BACKGROUND INFORMATION

Few fields of technology lack modern, electronically commutated drives. A steady development process is therefore taking place, in order to implement such drives in a more efficient manner and to make them effective for more and more applications, at the same time. For example, in many fields, so-called direct drives are becoming increasingly successful, whose torque is directly transmitted to the desired application, without using a transmission. Such direct drives are already available for very high torques, and, as linear direct drives, for very large forces.

Conditioned upon the design of such direct drives, such as described, for example, in European Published Patent Application No. 0 793 870, the inductances of many coils connected in series and parasitic capacitances have an ever more important part in the drive. In connection with a frequency converter for supplying the drive with energy, oscillatory systems are created having relatively low resonant frequencies in the range of a few 10 kHz.

Because of the switching procedures undertaken in the frequency converter, in the rectifier capable of feedback and in the inverter, the voltage at the neutral point of a connected multiphase load jumps with respect to ground. The resonance frequencies are excited in this context, under certain circumstances. In connection with such a frequency converter, oscillations may appear on direct drives having especially low resonant frequencies, which may lead to the destruction of the drive. Such high voltages may occur at the neutral point of the drive, in this context, that the insulation of the neutral point from ground is destroyed by partial discharge.

Various attempts have been made to address such problems. What is common to them all is that the undesired resonance vibrations are damped. In this context, one begins either directly in the drive or in the frequency converter.

German Published Utility Model No. 203 11 104 describes a current compensated choke looped into the intermediate circuit. It reduces the excitation of the interfering resonances. A disadvantage of this arrangement is the additional expenditure on rather large and costly components in the frequency converter.

In another connection, pulse width modulation methods are conventional in which the periodic control voltages for the phases of the connected load are added to a periodic voltage, that is the same for all phases, having a triple period. The voltage of the phases relative to one another does not change thereby. To avoid switching losses in the frequency converter, it is also conventional intermittently not to switch individual switching elements in the frequency converter.

### SUMMARY

Example embodiments of the present invention may provide a pulse width modulation method with which the excitement of resonances, at the neutral point of a connected load, is reduced.

A method is provided for the pulse width modulated control of switching elements in a frequency converter having N phases, in which control pulses of the switching elements are derived for each phase from respectively one P-periodic control voltage. The P-periodic control voltages correspond to a superposition of sinusoidal control voltages of period P offset by 360/N degrees with respect to each other with an N*P-periodic offset voltage that applies to all phases. The offset voltage, in this example, is selected such that, at any time, exactly one P-periodic control voltage, which affects the derivation of the switching pulses, lies on a modulating limit. If an overlap of control voltages on the modulating limit does occur, the time span of the overlap is small such that the overlap has little or no effect on the derivation of the switching pulses.

For analog controlled frequency converters, simple and cost-effective logical components are sufficient for the implementation of this method, so as to provide an appropriate control logic, and for digitally controlled frequency converters, the expenditure for implementing the method reduces to a software change.

Depending on whether a feedback-capable rectifier is to be operated using the pulse width modulation method, using which, energy is able to be fed from the intermediate circuit of a frequency converter back into the supply network, or an inverter that is to convert the direct voltage of the intermediate circuit into a multiphase alternating voltage for operating a load (e.g., of a motor), different arrangements of the pulse width modulation method may be provided.

According to an example embodiment of the present invention, a method for pulse width modulated control of switching elements in a frequency converter having N phases includes: for each phase, deriving switching pulses of the switching elements from a respective P-periodic control voltage, the P-periodic control voltages corresponding to superpositions of sinusoidal control voltages of a period P that are shifted by 360/N degrees with respect to one another, with an N*P-periodic offset voltage that applies to all of the phases. The offset voltage is selected such that, at any time, exactly one P-periodic control voltage lies on a modulating limit.

Each resulting control voltage may lie at least once during a period P in one region constantly on one of (a) an upper modulating limit and (b) a lower modulating limit.

For a period P of 360 degrees, each of the resulting control voltages may lie constantly on an upper modulating limit for two ranges each of 30 degrees and constantly on a lower modulating limit for two ranges each of 30 degrees.

Each of the resulting control voltages may lie constantly on one of (a) an upper modulating limit and (b) a lower modulating limit, during a period P of 360 degrees, for one range each of 120 degrees.

All constant ranges of the resulting control voltages may lie either on (a) the upper modulating limit or (b) the lower modulating limit.

The method may include suppressing a first switching pulse, following a constant range of a resulting control voltage not having switching pulses.

According to an example embodiment of the present invention, a method for pulse width modulated control of switching elements in a frequency converter having N phases includes: for each phase, deriving switching pulses of the switching elements from a respective P-periodic control voltage, the P-periodic control voltages corresponding to a superposition of sinusoidal control voltages of a period P that are shifted by 360/N degrees with respect to one another, with an N*P-periodic offset voltage that applies to all of the phases. The offset voltage is selected such that, at any time, one P-periodic control voltage lies on a modulating limit, and if more than one P-periodic control voltage lies on a modulating limit, a length of a time span of overlap of the P-periodic control voltages on the modulating limit is such that the overlap does not significantly affect the derivation of the switching pulses.

Further features and aspects of example embodiments of the present invention are described in more detail below with reference to the appended Figures.

### BRIEF DESCRIPTION OF THE DRAWINGS

FIG. 1 schematically illustrates an inverter having a connected load.

FIG. 2 illustrates a method for obtaining the usual PWM signals.

FIG. 3 illustrates several possible switching states of the load.

FIGS. 4a and 4b illustrate a method for obtaining improved PWM signals.

FIGS. 5a and 5b illustrate a method for obtaining improved PWM signals.

### DETAILED DESCRIPTION

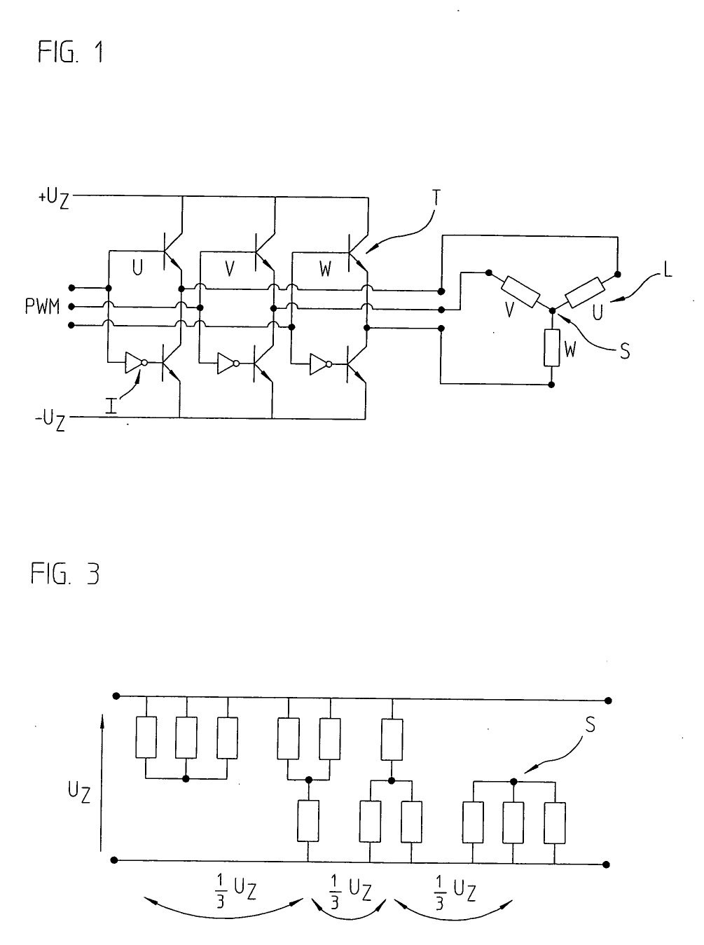

The left side of FIG. 1 illustrates an inverter, and the right side of FIG. 1 illustrates a load L, connected to the inverter, having three phases U, V, W. Load L may be a motor which is supplied with alternating voltage from an intermediate circuit whose direct voltage potentials are +U_{z} and −U_{z}. However, the following considerations apply also if load L is the supply network into which energy is to be fed back from the intermediate circuit, for example, because energy is produced in response to the braking of a motor. An excitation of the resonances, in the motor connected to the frequency converter, is also able to take place by the control of such a feedback-capable frequency converter.

Respectively, two switching elements T connect each phase U, V, W of load L either to +U_{z} or −U_{z} of the intermediate circuit. In the inverter there are, therefore, six switching elements T present. Power transistors such as IGBT's may be used for this.

Switching pulses in the form of three PWM signals are used to control switching elements T, and the PWM signals, as logical square-wave signals, control respectively one of the three phases. In each case, one switching element T is controlled directly by its assigned PWM signal, and the respectively corresponding switching element via an intermediately connected inverter I. Each bridge including switching elements T has two possible states, in which one of the two switching elements T is switched through and the other is blocked. Thereby each phase U, V, W of the load is applied either to +U_{z} or −U_{z}.

Referring to FIG. 2, a conventional method for the derivation of PWM signals from periodic control voltages is described. Three control voltages Us, Vs, Ws are considered, whose frequency and amplitude correspond to the voltage desired at the three phases U, V, W of load L. The objective is to approximate control voltages Us, Vs, Ws with the aid of pulse width modulated square-wave voltages. One possibility of achieving this is to compare these three control voltages Us, Vs, Ws in each case with a delta voltage Ud of constant frequency and constant amplitude. Depending on whether the respective control voltage Us, Vs, Ws is above or below delta voltage Ud, the appertaining PWM signal is switched to the one or the other logical state. The frequency of delta voltage Ud, in this context, is considerably higher than that of control voltages Us, Vs, Ws. Typically, the load-side frequency is 50 or 60 Hertz in a supply network, and in a motor the load-side frequency, and thus the frequency of the control voltages, depends on the (electrical) rotary speed of the motor. In contrast, the frequency of the delta voltage (also designated as PWM frequency) is in a range of several kHz, such as 5 to 10 kHz.

The amplitude of delta voltage Ud defines the modulating limit +A, −A for control voltages Us, Vs, Ws. Control voltage Us, Vs, Ws which are greater than this modulating limit, are not able to be converted by the PWM method into the corresponding voltages in phases U, V, W of load L.

Another conventional method for generating PWM signals is space phasor modulation.

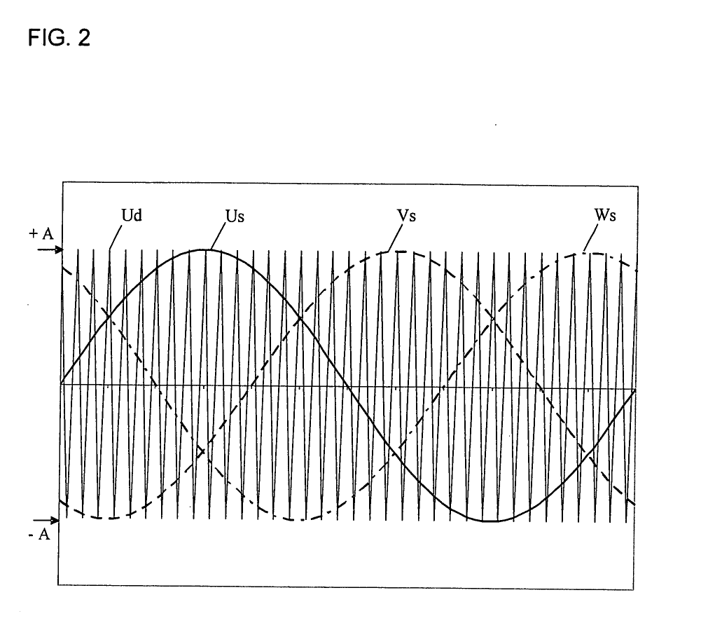

FIG. 3 illustrates various possible switching states of the individual phases U, V, W of load L that are connected in a star-shaped manner. If the voltage present at star or neutral point S is considered, it jumps by respectively ⅓*U_{z} between two adjacent switching states.

Depending on how many switching elements T switch at the same time (the possibilities are two, four or six) the voltage at star point S is able to change in jumps of ⅓*U_{z}, ⅔*U_{z} or 3/3*U_{z}. The greater the voltage jump at start point S, the more strongly excited are the undesired resonances.

Conventional pulse width modulation methods lead to numerous jumps of ⅔*U_{z} or even 3/3*U_{z}. Referring to FIG. 2, it should be recognized that, at each intersection of two control voltages Us, Vs, Ws, necessarily two switching element bridges simultaneously switch over, and that jumps of ⅔*U_{z} occur. If a voltage of 0 V is to be applied to a motor, all control curves lie on top of one another on the zero line of FIG. 2. Therefore, all six switching elements switch back and forth at the PWM frequency, in each case a 3/3*U_{z} jump occurring at the star point, and with that a very strong excitation of the resonances.

A pulse width modulation method is described below, which completely avoids jumps by ⅔*U_{z}. This method is above all suitable for feedback-capable network converters, since, in this instance, the just-described case of a setpoint voltage of constant 0 V does not occur, but the network voltage having the network frequency is always present. Jumps of the intermediate circuit voltage by more than ⅓*U_{z} are therefore excluded.

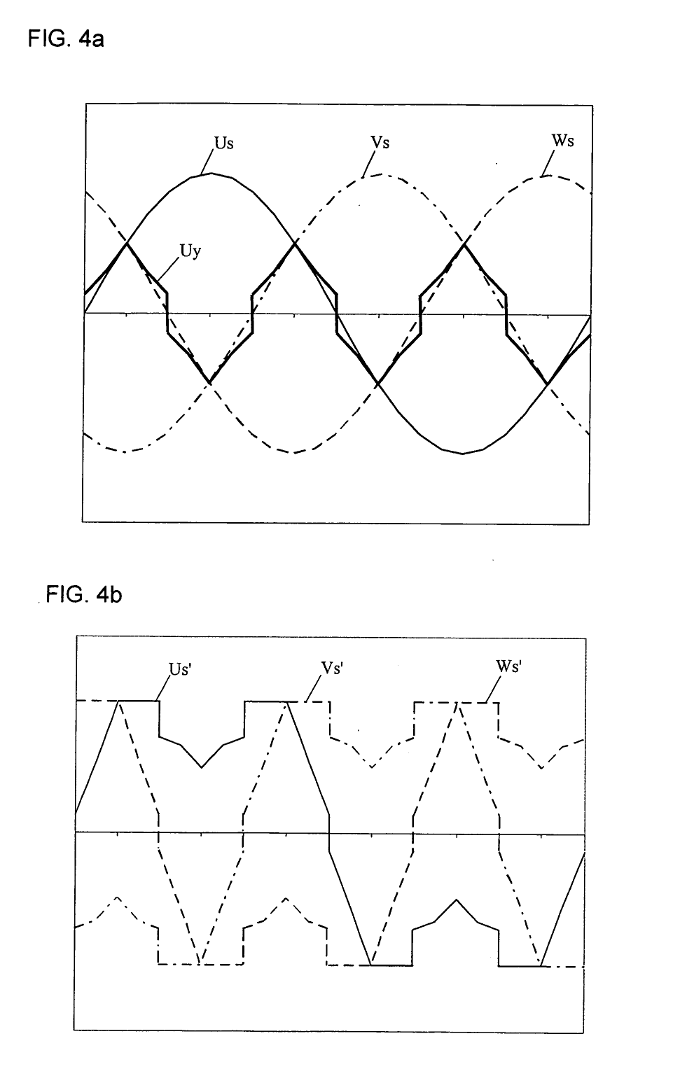

FIG. 4a illustrates sinusoidal control voltage Us, Vs, Ws of period P for a system having N=3 phases. Also illustrated is an N*P, that is, a 3*P-periodic offset voltage Uy, whose origination is explained below.

For control voltage Us′, Vs40 , Ws′ resulting from the superposition of the sinusoidal control voltage Us, Vs, Ws with offset voltage Uy, illustrated in FIG. 4b, first of all, the following applies:
Us′=Us+Uy;
Vs′=Vs+Uy; and
Ws′=Ws+Uy.

Offset voltage Uy is selected such that the superposition of offset voltage Uy with each of the P-periodic control voltages Us, Vs, Ws leads to, at any time, exactly one of the resulting P-periodic control voltages Us′, Vs′, Ws′ lying upon a modulating limit of delta voltage Ud. The resulting control voltages Us′, Vs′, Ws′ intersect only on a modulating limit +A, −A.

In particular, in each case a resulting control voltage Us′, Vs′, Ws′ for a 30 degree section of a 360 degree period P should lie on a modulating limit +A, −A, and, indeed, in each case, two 30 degree sections on the upper modulating limit and in each case two 30 degree sections on the lower modulating limit. Thus, there comes about for offset voltage Uy of FIG. 4a (using interval notation according to ISO 31-11):

In the interval [0 degrees; 30 degrees[, that is 0°≦x<30°: Uy=A−Ws (Ws′ lies on A)

In the interval [30 degrees; 60 degrees[, that is 30°≦x<60°: Uy=A−Us (Us′ lies on A)

In the interval [60 degrees; 90 degrees[, that is 60°≦x<90°: Uy=−A−Vs (Vs′ lies on −A)

In the interval [90 degrees; 120 degrees[, that is 90°≦x<120°: Uy=−A−Ws (Ws′ lies on −A)

This defines offset voltage Uy for the first third of period P, and the curve repeats in the second and third one-third, since the offset voltage is 3*P-periodic.

FIG. 4b illustrates control voltage Us′, Vs′, Ws′, which result from the superposition of control voltages Us, Vs, Ws of FIG. 4a, using offset voltage Uy that was just derived above. Since offset voltage Uy is intruded on each of the three sinusoidal control voltages Us, Vs, Ws, nothing changes in the voltage difference between phases U, V, W that is decisive for load L, if, instead of sinusoidal control voltages Us, Vs, Ws of FIG. 4a, one uses the resulting control voltages Us′, Vs′, Ws′ of FIG. 4b.

Offset voltage Uy is selected such that each of control voltages Us′, Vs′, Ws′, per period P, lies four times on the upper or lower modulating limit +A, −A, for 30 degrees, that is, a 1/12 period. The PWM signal thus ascertained is static during these times, that is, it does not effect any switching procedures for the respectively assigned phases U, V, W. The four constant regions each lie twice on upper modulating limit A and each twice on lower modulating limit −A. Between the constant regions there lie in each case regions in which the control voltage runs between the extreme values and partially even jumps.

What is decisive is that intersections between control voltages Us′, Vs′, Ws′ lie exclusively in regions in which one of the two intersecting control voltages Us′, Vs′, Ws′ is just still constant, and the other of the two is constant from the intersection on. Expressed differently, before each intersection and after each intersection there is a region in which one of the two control voltages Us′, Vs′, Ws′ is constant, and, actually, in this instance, in a region of 30 degrees of one period. This has the result that two phases U, V, W of load L are never simultaneously switched over, and therewith leads to a complete avoidance of ⅔*U_{z} jumps from the intermediate circuit to ground. The excitement of resonances is thereby clearly reduced.

With respect to the excitation of resonances, the amplitude of the voltage jump is not exclusively the deciding factor, but a sequence of several jumps by ⅓*U_{z} in the same direction is also able to generate an exceptionally great excitation if the distance of the individual jumps falls in the range of the rise time of the self-resonance of star point S. Such consecutive jumps occur, under certain circumstances, in response to the change of one control voltage Us′, Vs′, Ws′ to another one, in continuous operation. Since at the beginning of such a transition, the pulse width of the PWM signal from the intersection of delta voltage Ud with control voltage Us′, Vs′, Ws′, that just no longer lies on the control limit, is narrow, the first consequent pulse after the change is able to be suppressed by a suitable circuit, without great interference in the currents effected in load L, which leads to a further reduction in the overvoltage at star point S of load L.

Thus, the first PWM switching pulse following a constant range of a control voltage Us′, Vs′, Ws′ not having PWM control pulses (that is, the first two switchover procedures of the respective switching element bridge) may be suppressed.

The foregoing pulse width modulation method may not be suitable for controlling a load in which a setpoint voltage of 0 V or very low setpoint voltages occur, as will happen in a motor at rest or rotating very slowly. Therefore, for such applications, an additional pulse width modulation method is described that is suitable for such purposes.

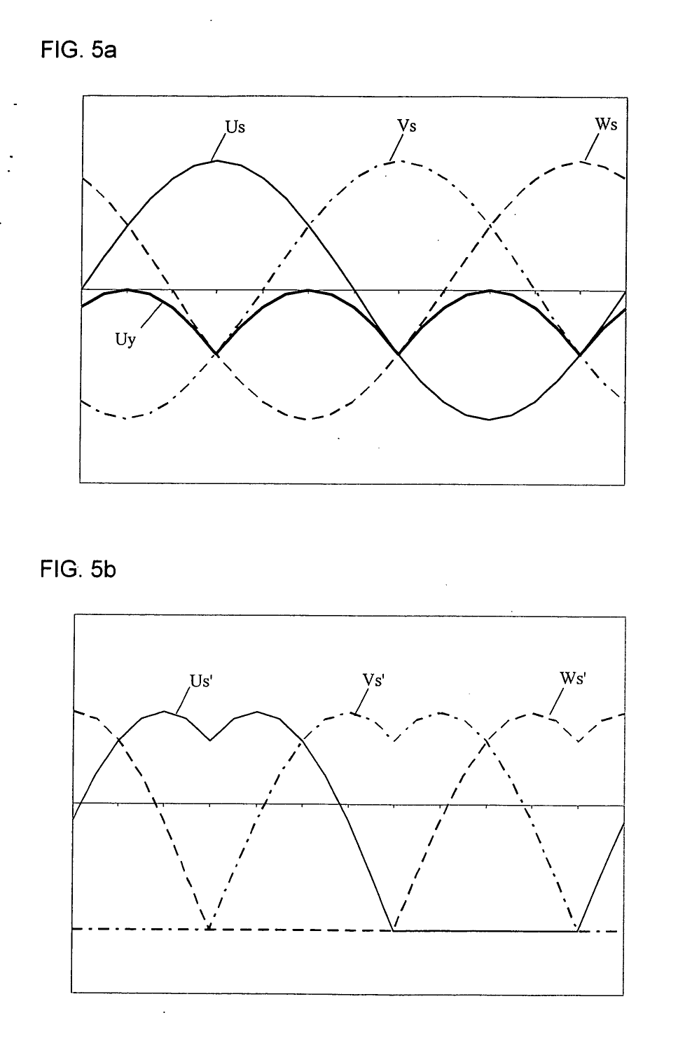

FIG. 5a illustrates sinusoidal, P-periodic control voltages Us, Vs, Ws, as well as a 3*P periodic offset voltage Uy (for 3 phases). In the following, the derivation of this offset voltage Uy is explained.

The condition for control voltage Us′, Vs′, Ws′ resulting from the superposition of sinusoidal control voltages Us, Vs, Ws by offset voltage Uy is the same as in the above-described exemplary embodiment, namely, that at each time exactly one of the P-periodic control voltages Us′, Vs′, Ws′ lies on a control limit +A, −A of delta voltage Ud

In this exemplary embodiment, the regions that lie constantly on control limit +A, −A extend in each case over 120 degrees, so that, per period P, each resulting control voltage Us′, Vs′, Ws′ lies once for 120 degrees on a modulating limit +A, −A.

Besides that, 3*P periodic offset voltage Uy is selected such that the resulting control voltages each lie only on one of the two, in the example, on the lower, negative control limit −A.

From these boundary conditions, the following conditional equations (using interval notation according to ISO 31-11) are derived for offset voltage Uy:

In the interval [0 degrees; 90 degrees[, that is 0°≦x<90°: Uy=−A−Vs (Vs′ lies on −A)

In the interval [90 degrees; 210 degrees[, that is 90°≦x<210°: Uy=−A−Ws (Ws′ lies on −A)

In the interval [210 degrees; 330 degrees[, that is 210°≦x<330°: Uy=−A−Us (Us′ lies on −A)

In the interval [330 degrees; 360 degrees[, that is 330°≦x<360°: Uy=−A−Vs (Vs′ lies on −A)

The first and last interval of this listing supplement each other to a range of 120 degrees, in which Ws′ lies constantly on the lower, negative control limit −A. Thus, Uy is 3*P periodic here, too.

This form of the resulting control voltages Us′, Vs′, Ws′ also reduces the number of ⅔*U_{z} jumps, since at least a part of the intersections among control voltages Us′, Vs′, Ws′ lie on control limit +A, −A. Jumps by 3/3*U_{z} are completely avoided. However, this method may be particularly suitable in which a motor that is standing or rotating only very slowly is to be controlled as load L. All control voltages Us′, Vs′, Ws′ in this case lie on the lower modulating limit −A, and no further switching procedures occur.

The exemplary embodiment first described above is thus suitable above all for the rectifier capable of feedback, which, in a frequency converter for the activation of a motor, rectifies the network voltage for the intermediate circuit, and, if required, is able to feed back energy from the intermediate circuit of the frequency converter into the network. Load L illustrated in FIG. 1 represents the network. In this case, since control voltages Us′, Vs′, Ws′ always follow the network, there are neither ⅔*U_{z} jumps nor 3/3*U_{z} jumps. Since control voltages Us′, Vs′, Ws′ remain alternatingly on the upper and the lower modulating limit, switching elements T are on average loaded equally strongly.

The exemplary embodiment secondly described above, on the other hand, is suitable for the inverter, which, in a frequency converter, generates an alternating voltage of any frequency and amplitude from the direct voltage of the intermediate circuit, for controlling motor phases U, V, W. Load L illustrated in FIG. 1, in this case, represents the motor. In response to the standstill of the motor, neither ⅔*U_{z} nor 3/3*U_{z} jumps occur. If the motor rotates, the number of ⅔*U_{z} jumps is reduced. The method according to the second exemplary embodiment is therefore to be considered preferable to the method according to the first exemplary embodiment for this application, despite an uneven load of switching elements T.

In both exemplary embodiments, the number of switching procedures of switching elements T is reduced to approximately ⅔ of the value at the usual, sinusoidal control voltage, and therewith also the excitation of undesired resonances. However, since, along with this, the ripple of the currents generated in phases U, V, W also increases by a factor of 1.5, the PWM frequency, that is, the frequency of delta voltage Ud, also has to be raised by this factor 1.5, in order to compensate for this ripple.

It should still be mentioned at this point that, at certain points in time, two resulting control voltages Us′, Vs′, Ws′ may also lie on one modulating limit +A, −A, namely, if one of the control voltages still just lies on the modulating limit, and the other control voltage is just arriving at the modulating limit. Within the scope of accuracy that is possible at all for the generation of such control voltage Us′, Vs′, Ws′, this overlapping state is able to keep going, even for a short interval. What is significant is that this time span is small in comparison to the period duration of delta voltage Ud, because then such brief overlapping is not important in the formation or derivation of the PWM signals. The expression “at any time exactly one” should be understood to mean that never does an overlapping of resulting control voltages Us′, Vs′, Ws′, that is effective for the formation of the PWM signals, appear on a modulating limit +A, −A.

What is claimed is:

1. A method for pulse width modulated control of switching elements in a frequency converter having N phases, comprising:
for each phase, deriving switching pulses of the switching elements from a respective P-periodic control voltage, the P-periodic control voltages corresponding to a superposition of sinusoidal control voltages of a period P that are shifted by 360/N degrees with respect to one another, with an N*P-periodic offset voltage that applies to all of the phases;
wherein the offset voltage is selected such that, at any time, exactly one P-periodic control voltage lies on a modulating limit.

2. The method according to claim 1, wherein each resulting control voltage lies at least once during a period P in one region constantly on one of (a) an upper modulating limit and (b) a lower modulating limit.

3. The method according to claim 1, wherein, for a period P of 360 degrees, each of the resulting control voltages lies constantly on an upper modulating limit for two ranges each of 30 degrees and lies constantly on a lower modulating limit for two ranges each of 30 degrees.

4. The method according to claim 1, wherein each of the resulting control voltages lies constantly on one of (a) an upper modulating limit and (b) a lower modulating limit, during a period P of 360 degrees, for one range each of 120 degrees.

5. The method according to claim 4, wherein all constant ranges of the resulting control voltages lie either on (a) the upper modulating limit or (b) the lower modulating limit.

6. The method according to claim 1, further comprising suppressing a first switching pulse, following a constant range not having switching pulses.

7. A method for pulse width modulated control of switching elements in a frequency converter having N phases, comprising:
for each phase, deriving switching pulses of the switching elements from a respective P-periodic control voltage, the P-periodic control voltages corresponding to a superposition of sinusoidal control voltages of a period P that are shifted by 360/N degrees with respect to one another, with an N*P-periodic offset voltage that applies to all of the phases;
wherein the offset voltage is selected such that, at any time, one P-periodic control voltage lies on a modulating limit, and if more than one P-periodic control voltage lies on a modulating limit, a length of a time span of overlap of the P-periodic control voltages on the modulating limit is such that the overlap does not significantly affect the derivation of the switching pulses.
